(19) United States
(12) Patent Application Publication
(10) Pub. No.: US 2022/0071060 A1
(43) Pub. Date: Mar. 3, 2022

(54) THIN VAPOR CHAMBER

(71) Applicant: Auras Technology Co., Ltd., New Taipei City (TW)

(72) Inventors: Chih-Wei CHEN, New Taipei City (TW); Tien-Yao CHANG, New Taipei City (TW); Che-Wei KUO, New Taipei City (TW)

(21) Appl. No.: 17/410,511

(22) Filed: Aug. 24, 2021

Related U.S. Application Data
(60) Provisional application No. 63/073,593, filed on Sep. 2, 2020.

(51) Int. Cl. H05K 7/20; F28D 15/02; F28D 15/04

(52) U.S. Cl. CPC H05K 7/20336; F28D 15/046; H05K 7/2039; F28D 15/0233

(57) ABSTRACT

A thin vapor chamber is provided. The thin vapor chamber includes an upper plate, a lower plate, and a plurality of solid columns. The lower plate is opposite to the upper plate, and the upper plate and the lower plate are combined to form a closed space. The solid column is formed on the upper plate and extends to the lower plate. The solid columns are located in the closed space. The solid columns respectively have at least one capillary groove, and a first portion of an inner surface of the capillary groove faces a second portion of the inner surface.

### RELATED APPLICATIONS

This application claims priority to U.S. Provisional Application Ser. No. 63/073,593, filed Sep. 2, 2020, the disclosures of which are incorporated herein by reference in their entireties.

### TECHNICAL FIELD

The present disclosure generally relates to solid columns of a thin vapor chamber to improve an efficiency of transporting heat dissipation liquid.

### BACKGROUND

The statements in this section merely provide background information related to the present disclosure and do not necessarily constitute prior art.

In recent years, the thin vapor chamber (VC) has gradually been utilized in mobile devices. The manufacturing process of the vapor chamber requires high-temperature to sinter capillary structures, or perform heating processes such as welding. These heating processes may cause copper alloy to fully anneal and soften, so that the strength of the finished vapor chamber is much lower than the strength of the product used the same copper alloy, such as connectors, lead frames, spring plates and any other parts.

Therefore, the interior of the vapor chamber needs a support structure, and common support structures can be cylindrical or square columns arranged in an array at a fixed interval, or ribs or a mixed support structure design in a specific region. These support structures can be divided into two types, for example, solid copper columns or sintered copper powder columns.

### SUMMARY

However, in the thin vapor chamber, due to process limitations, the support structure is basically completed by etching, and the powder sintering process cannot be applied to the thin vapor chamber. Therefore, the supporting structure of the thin vapor chamber of the current mobile phone is only utilized with etched columns to support the thin vapor chamber, and the sintered powder columns having the transporting liquid function are therefore discarded.

To achieve these and other advantages and in accordance with the objective of the embodiments of the present disclosure, as the embodiment broadly describes herein, the embodiments of the present disclosure provides a thin vapor chamber including etched solid columns able to support the upper plate and the lower plate and transport liquid. The thin vapor chamber includes an upper plate, a lower plate and a plurality of solid columns. The lower plate is disposed opposite to the upper plate and the upper plate and the lower plate are combined to form a closed space. The solid columns are formed on the upper plate and extended to the lower plate. The solid columns are located in the closed space. The solid columns respectively have at least one capillary groove, and a first portion of an inner surface of the capillary groove faces a second portion of the inner surface.

In some embodiments, the capillary groove has an opening, a third portion of the inner surface faces the opening, and the first portion and the second portion are connected to each other through the third portion.

In some embodiments, the upper plate and the lower plate are combined to form a gas extraction tunnel. The gas extraction tunnel is connected to the closed space. A first width, vertically to the gas extraction direction, of the gas extraction tunnel is smaller than a second width, vertically to the gas extraction direction, of the closed space, and the opening of the capillary groove faces a direction other than a direction toward the gas extraction tunnel.

In some embodiments, surfaces, facing the gas extraction tunnel, of the solid columns are smooth arc or flat surfaces without grooves.

In some embodiments, a perimeter, projected on the upper plate, of a solid portion of one selected solid column having a capillary groove of the solid columns is greater than a reference perimeter, projected on the upper plate, of one reference solid column of the selected solid column when the capillary groove is filled.

In some embodiments, each maximum lateral length of the solid columns is between 0.5 mm and 2 mm.

In some embodiments, a minimum width of the capillary groove is between 0.005 mm and 0.03 mm.

In some embodiments, a minimum width of the capillary groove is between 0.02 mm and 0.2 mm.

In some embodiments, at least one of the solid columns further comprises an elevated portion surrounded and located at a periphery of the at least one of the solid columns to form a liquid adsorption space.

Hence, the present disclosure utilizes the solid columns having appropriate grooves to form capillary grooves so as to support the thin vapor chamber and transporting the heat dissipation liquid with the capillary force.

### BRIEF DESCRIPTION OF THE DRAWINGS

The foregoing aspects and many of the attendant advantages of this invention will be more readily appreciated as the same becomes better understood by reference to the following detailed description, when taken in conjunction with the accompanying drawings, wherein:

FIG. 1 illustrates a schematic exploded view showing a thin vapor chamber according to some embodiments of the present disclosure;

FIG. 2 is an enlarged schematic view showing a partial region of a thin vapor chamber according to some embodiments of the present disclosure;

FIG. 3 is a three-dimensional schematic diagram of one solid column according to another embodiment of the present disclosure;

FIG. 4 is a three-dimensional schematic diagram of one solid column according to further another embodiment of the present disclosure;

FIG. 5 is a three-dimensional schematic diagram of one solid column according to still another embodiment of the present disclosure;

FIG. 6 is a three-dimensional schematic diagram of one solid column according to still further another embodiment of the present disclosure;

FIG. 7 is a three-dimensional schematic diagram of one solid column according to still further another embodiment of the present disclosure; and

FIG. 8 is a schematic top perspective view of a thin vapor chamber according to some embodiments of the present disclosure.

### DETAILED DESCRIPTION OF THE PREFERRED EMBODIMENT

The following description is of the best presently contemplated mode of carrying out the present disclosure. This description is not to be taken in a limiting sense but is made merely for the purpose of describing the general principles of the invention. The scope of the invention should be determined by referencing the appended claims.

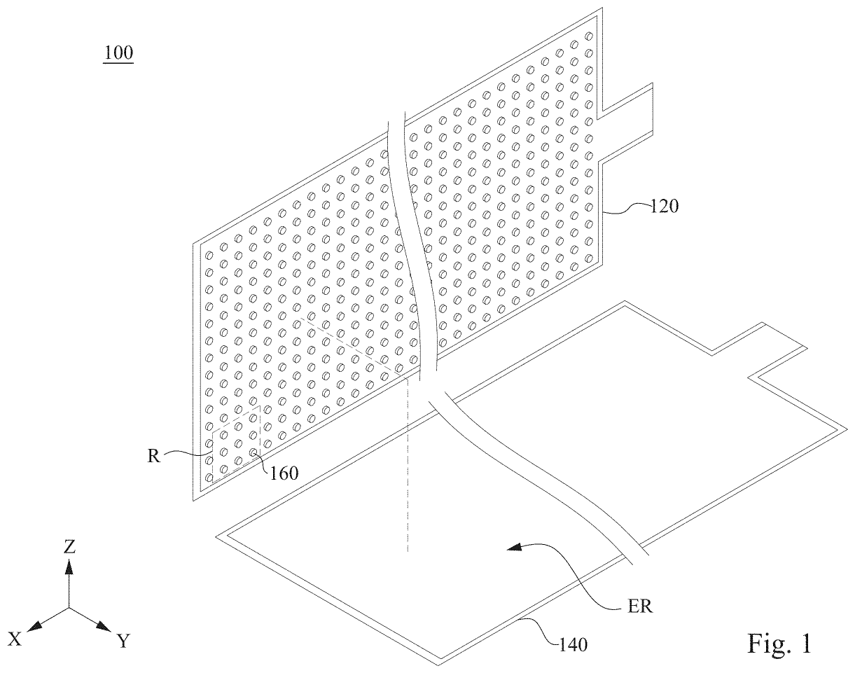

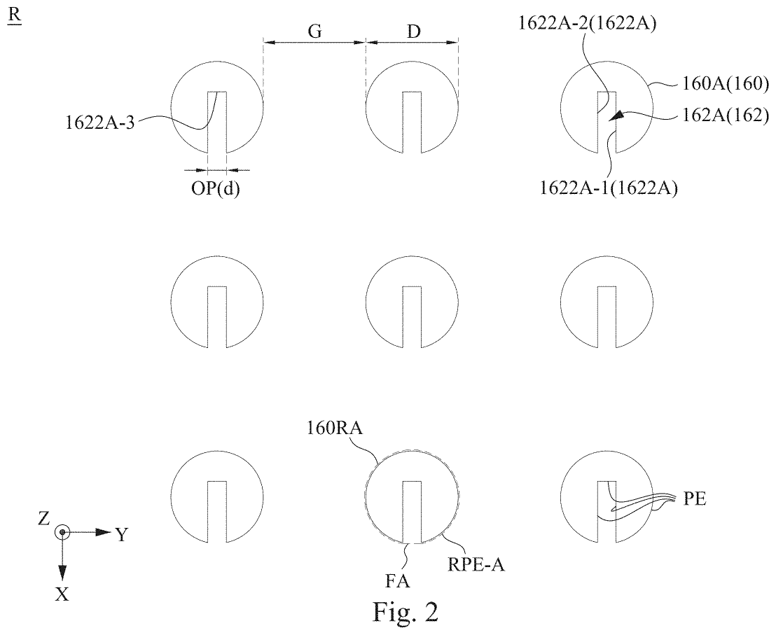

FIG. 1 is a schematic exploded view showing a thin vapor chamber 100 according to some embodiments of the present disclosure. The thin vapor chamber 100 includes an upper plate 120, a lower plate 140 and a plurality of solid columns 160. FIG. 2 is an enlarged schematic view showing a partial region R of a thin vapor chamber according to some embodiments of the present disclosure. FIG. 2 is focused on the description of the solid columns 160 to illustrate a cross-sectional view of the solid columns 160 along the X-Y plane. Simultaneously refer to FIG. 1 and FIG. 2. The lower plate 140 is disposed opposite to the upper plate 120, and the upper plate 120 and the lower plate 140 are combined to form a closed space ER. After the thin vapor chamber 100 is produced, the heat dissipation liquid, e.g. water, is basically isolated in the closed space ER. The upper plate 120 and the lower plate 140 are made of copper, but the present disclosure is not limited thereto.

The solid columns 160 are formed on the upper plate 120 and extended to the lower plate 140. The solid columns 160 are located in the closed space ER. First, refer to FIG. 2. FIG. 2 illustrates solid columns 160A, and the solid columns 160A respectively have at least one capillary groove 162A (162). A first portion 1622A-1 of an inner surface 1622A of the capillary groove 162A faces a second portion 1622A-2 of the inner surface 1622A. In some embodiments, the capillary groove 162A includes an opening OP. A third portion 1622A-3 of the inner surface 1622A faces the opening OP, and the first portion 1622A-1 and the second portion 1622A-2 are connected to each other through the third portion 1622A-3. The foregoing inner surfaces 1622A are surfaces, depressed in the solid columns 160A, of the capillary groove 162A, and these surfaces face solid portions of the solid columns 160A. Only one surface, e.g. a third portion 1622A-3, connected between the surfaces faced solid portions of the solid columns 160A faces the opening OP.

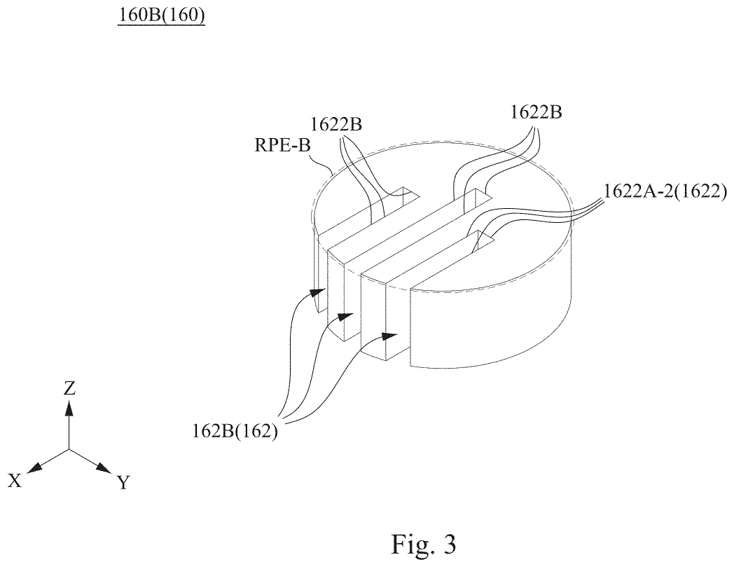

In some embodiments, a perimeter PE is a peripheral length of the solid portion of the solid column 160 projected on the upper plate 120. A reference perimeter RPE-A is a peripheral length, projected on the upper plate 120, of the solid column 160 when the capillary groove 162A is filled as shown a reference solid column 160RA illustrated by dashed lines in FIG. 2. The perimeter PE is greater than the reference perimeter RPE-A. In addition, a definition of the reference perimeters RPE-B, RPE-C, RPE-D and RPE-E shown in FIG. 3 to FIG. 6 is the same definition of the reference perimeter RPE-A in FIG. 2, and it will not repeat in the following description. Filling the capillary groove 162A means to fill the space between an imaginary surface FA created by connecting the apexes of the first portion 1622A-1 and the second portion 1622A-2 of the inner surface 1622A intersected with the opening OP. Taking the solid column 160A as an example, the perimeter PE of the solid column 160A with the capillary groove 162A is longer than a perimeter of a solid column without the capillary groove so as to improve the capillarity capacity of the solid column and efficiently transport more cooling liquid. Although the description of the foregoing embodiment takes the solid column 160A of FIG. 2 as an example, it can also be applied to subsequent solid columns 160 with other shapes.

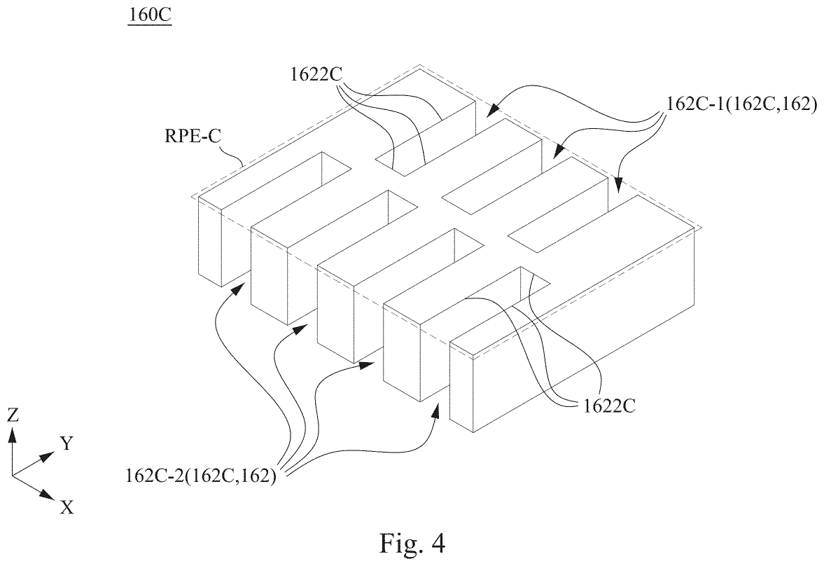

FIG. 2 is illustrated solid columns 160A having capillary grooves 162A according to one embodiment of the present disclosure, and the capillary grooves 162A are respectively recessed toward centers of the solid columns 160A. In some embodiments, the number of the capillary groove 162 can be multiple. FIG. 3 is a perspective view showing a solid column 160B according to another embodiment of the present disclosure. As compared with FIG. 2, three parallel capillary grooves 162B are illustrated in FIG. 3, and a reference perimeter RPE-B is also illustrated therein. FIG. 4 is a perspective view showing a solid column 160C according to further another embodiment of the present disclosure. The solid column 160C has a rectangular shape while projected on the upper plate 120. That is to say, the reference perimeter RPE-C is rectangular. The capillary grooves 162C can be divided into two groups, openings OP of three upper groups of capillary groove 162C-1 are opposite to openings OP of four lower groups of capillary groove 162C-2, that is, the capillary grooves 162C-1 and the capillary grooves 162C-2 are in a back-to-back structure. In addition, the inner surfaces 1622B, 1622C in FIG. 3 and FIG. 4 are similar to the inner surface 1622A in FIG. 2, and it will not repeat again.

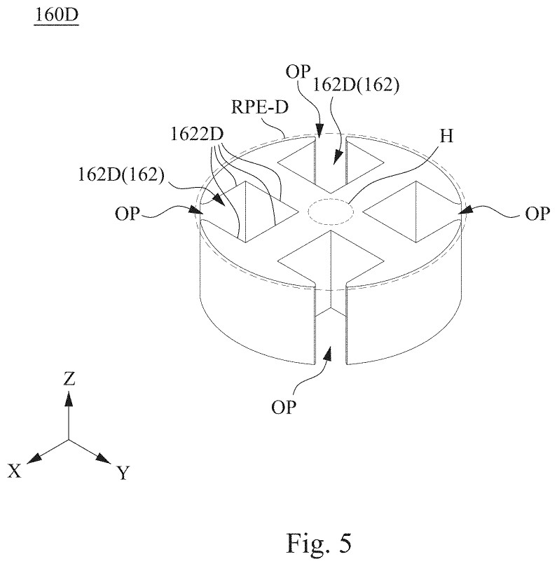

FIG. 5 is illustrated a perspective view showing a solid column 160D according to still another embodiment of the present disclosure. A reference perimeter RPE-D of the solid column 160D is round or elliptical having radial capillary grooves 162D. That is, the openings OP of the capillary grooves 162D are radially formed around a center of the reference perimeter RPE-D. In addition, in some embodiments, the openings OP of the capillary grooves 162D are narrower and inner grooves thereof are wider, so as to further improve the water transportation efficiency. In some embodiments, a center portion of the solid column 160D illustrated with dashed lines is a hole H. The hole H is different from the capillary groove 162D, the capillary groove 162D has an opening OP along the side wall of the capillary groove 162 and the hole H has no such an opening. The hole H has axial openings along the axial direction (Z direction) of the capillary groove 162D as shown in FIG. 5. As shown in FIG. 5, the quantity of the inner surfaces 1622D of the solid column 160D is four, and two of them look at the other two, that is, two groups of the inner surfaces 1622D are look at each other.

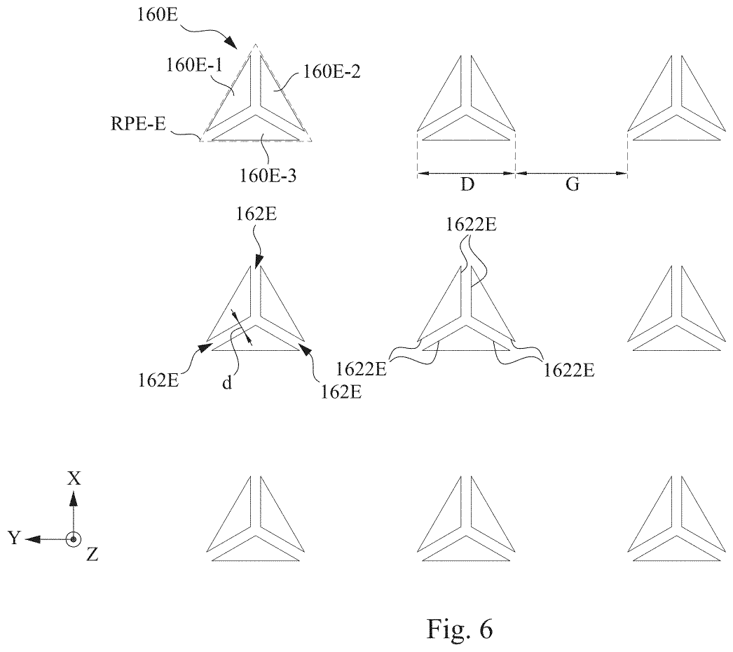

FIG. 6 is illustrated a cross sectional view of solid columns 160E according to still further another embodiment of the present disclosure. In some embodiments, each of the solid columns 160E may have a plurality of separated solid portions, for example, three solid portions as a group to form a unit. In some embodiments as illustrated in FIG. 6, capillary grooves 162E are formed between two of the first physical portion 160E-1, the second physical portion 160E-2 and the third physical portion 160E-3 of one group of the solid columns 160E to transport the heat dissipation liquid. A reference perimeter RPE-E of the solid column 160E is also illustrated in FIG. 6, and is triangular. The quantity of the inner surfaces 1622E of the solid column 160E is six, and two are formed on the first physical portion 160E-1, two are formed on the second physical portion 160E-2 and two are formed on the third physical portion 160E-3. In addition, two of the inner surfaces 1622E are look at each other, and three groups of the inner surfaces 1622E are illustrated in FIG. 6 as compared with two groups of the inner surfaces 1622D are illustrated in FIG. 5.

In some embodiments, a maximum lateral length D of the solid columns 160 is between 0.5 mm and 2 mm. In some embodiments, a minimum width d of the capillary grooves 162 is between 0.005 mm and 0.03 mm. In another embodiment, a minimum width d of the capillary grooves 162 is between 0.02 mm and 0.2 mm to achieve a better heat dissipation liquid efficiency. In addition to considering the performance of capillary phenomena, the choice of minimum width d also considers the feasibility of the process technology. Furthermore, the gaps G between the solid columns 160 are vapor channels for the thin vapor chamber 100, and a larger gap G can provide a smooth vapor channel to provide a better heat dissipation efficiency for the thin vapor chamber 100. Taking into account the balance of the performance of the capillary groove 162 to transport heat dissipation liquid, the gap G can be between 0.505 mm and 2.2 mm. In another embodiment, the gap G is between 1.2 mm and 2 mm, the thin vapor chamber 100 can provide a better heat dissipation efficiency.

The manufacturing method of solid columns 160 mentioned in the foregoing various embodiments is limited to non-sintered type because the manufacturing method is applied to thin vapor chamber 100 to complete by etching.

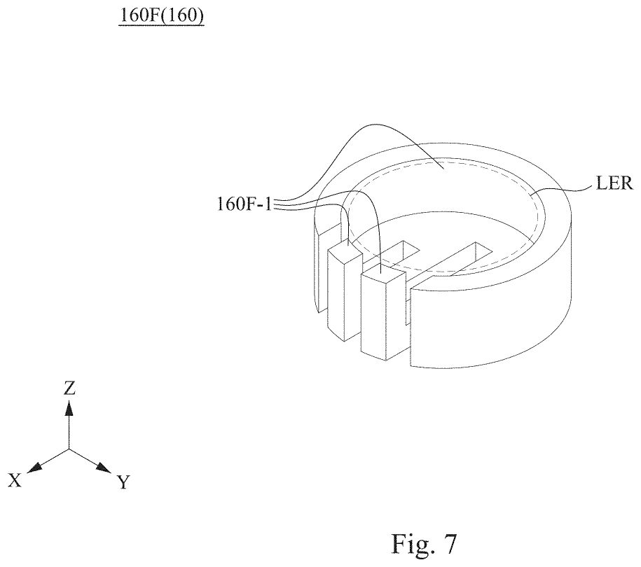

Refer to FIG. 7. FIG. 7 is a perspective view showing a solid column 160F according to still further another embodiment of the present disclosure. The solid column 160F is conformally extended along the periphery of reference perimeter RPE-B of the solid column 160B of FIG. 3. As shown in FIG. 7, an elevated portion 160E-1 is formed in the solid columns 160F as compared with the solid columns 160B. The elevated portion 160E-1 contacts the upper plate 120 and surrounds the solid column 160F to form a liquid adsorption space LER around the solid column 160F to increase a more liquid storage capacity as compared with the solid column 160B so as to preserve more heat dissipation liquid.

According to the same concept as above, the solid columns 160C, 160D, 160E are conformally extended along the periphery of the reference perimeters RPE-C, RPE-D, RPE-E of the solid columns 160C, 160D, 160E to increase the liquid storage capacity of solid columns 160C, 160D, 160E, and similar diagrams are omitted here and are not repeated again.

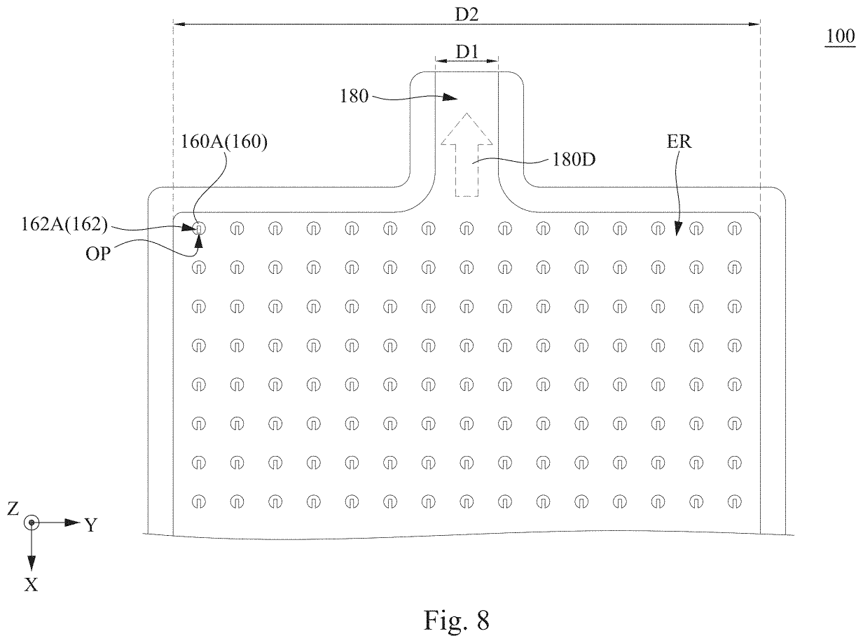

Refer to FIG. 8. FIG. 8 is a schematic top perspective view of a thin vapor chamber 100 according to some embodiments of the present disclosure. The top perspective view can directly illustrate the closed space ER and the solid columns 160. The solid column 160A is an example of the solid column 160. The other solid columns 160B, 160C, 160D, 160E and 160F can be located at the positions of the solid columns 160A of FIG. 8 while satisfying the following requirements. In the thin vapor chamber 100 manufacturing process, after the solid columns 160 are welded to the upper plate 120 and the lower plate 140, the thin vapor chamber 100 may fill with a heat dissipation liquid. Subsequently, the thin vapor chamber 100 is formed a closed space ER after the thin vapor chamber 100 is evacuated through the gas extraction tunnel 180. The foregoing gas extraction tunnel 180 is formed by the combination of the upper plate 120 and the lower plate 140, and the gas extraction tunnel 180 is communicated with the closed space ER. A first width D1, perpendicular to the gas extraction direction 180D, of the gas extraction tunnel 180 is smaller than a second width D2, perpendicular to the gas extraction direction 180D, of closed space ER.

Generally speaking, the heat dissipation liquid injecting process and vacuuming process are trade-off processes. In order to achieve a better vacuum value, a less amount of the heat dissipation liquid may store in the closed space ER. If a more amount of the heat dissipation liquid stored in the closed space ER is needed, the vacuum quality thereof must be sacrificed, and the sacrifice of the vacuum quality may reduce the heat dissipation efficiency of the thin vapor chamber 100. In order to increase the amount of the heat dissipation liquid stored in the closed space ER as well as maintain a high vacuum quality at the same time, in some embodiments of the present disclosure, the openings OP of the solid columns 160A are directed toward a direction other than the gas extraction tunnel 180 in the thin vapor chamber 100, and even the openings OP directly face back the gas extraction tunnel 180. In an embodiment shown in FIG. 8, the opening OP may face the X direction and face away from the gas extraction tunnel 180, a negative X direction (a gas extraction direction 180D as illustrated in FIG. 8). In other words, if one looks from the gas extraction tunnel 180 to the closed space ER, no capillary groove 162 is visible and only smooth arc or flat surfaces without grooves of the solid columns 160 can be seen. The smooth arc or flat surfaces mentioned here are based on the size of the capillary groove 162 for storing the heat dissipation liquid compared with the scale of the thin vapor chamber 100. If the roughness of the unevenness is significantly smaller than the capillary groove 162 can be considered as smooth.

Accordingly, the embodiments of the present disclosure provide a thin vapor chamber with etched solid columns, and these solid columns include various capillary grooves disclosed in this disclosure through an appropriate size design can achieve the dual functions of supporting the thin vapor chamber and transporting the heat dissipation liquid. In addition, the opening directions of the solid columns face back or at least not face the gas extraction tunnel to allow the thin vapor chamber able to store the heat dissipation liquid and increase the vacuum during the manufacturing process, so that the quality of the thin vapor chamber is greatly improved.

As is understood by a person skilled in the art, the foregoing preferred embodiments of the present disclosure are illustrative of the present disclosure rather than limiting of the present disclosure. It is intended that various modifications and similar arrangements be included within the spirit and scope of the appended claims, the scope of which should be accorded the broadest interpretation so as to encompass all such modifications and similar structures.

What is claimed is:

1. A thin vapor chamber, comprising:
an upper plate;
a lower plate disposed opposite to the upper plate, wherein the upper plate and the lower plate are combined to form a closed space; and
a plurality of solid columns formed on the upper plate and extended to the lower plate, the solid columns are located in the closed space, wherein the solid columns respectively have at least one capillary groove, and a first portion of an inner surface of the capillary groove faces a second portion of the inner surface.

2. The thin vapor chamber of claim 1, wherein the capillary groove has an opening, a third portion of the inner surface faces the opening, and the first portion and the second portion are connected to each other through the third portion.

3. The thin vapor chamber of claim 1, wherein the upper plate and the lower plate are combined to form a gas extraction tunnel, the gas extraction tunnel is connected to the closed space, a first width, vertically to a gas extraction direction, of the gas extraction tunnel is smaller than a second width, vertically to the gas extraction direction, of the closed space, and an opening of the capillary groove faces a direction other than a direction toward the gas extraction tunnel.

4. The thin vapor chamber of claim 1, wherein the upper plate and the lower plate are combined to form a gas extraction tunnel, the gas extraction tunnel is connected to the closed space, a first width, vertically to a gas extraction direction, of the gas extraction tunnel is smaller than a second width, vertically to the gas extraction direction, of the closed space, and surfaces, facing the gas extraction tunnel, of the solid columns are smooth arc or flat surfaces without grooves.

5. The thin vapor chamber of claim 1, wherein a perimeter, projected on the upper plate, of a solid portion of one selected solid column having a capillary groove of the solid columns is greater than a reference perimeter, projected on the upper plate, of one reference solid column of the selected solid column when the capillary groove is filled.

6. The thin vapor chamber of claim 1, wherein each maximum lateral length of the solid columns is between 0.5 mm and 2 mm.

7. The thin vapor chamber of claim 1, wherein a minimum width of the capillary groove is between 0.005 mm and 0.03 mm.

8. The thin vapor chamber of claim 1, wherein a minimum width of the capillary groove is between 0.02 mm and 0.2 mm.

9. The thin vapor chamber of claim 1, wherein at least one of the solid columns further comprises an elevated portion surrounded and located at a periphery of the at least one of the solid columns to form a liquid adsorption space.
